(19) United States
(12) Patent Application Publication
(10) Pub. No.: US 2024/0396298 A1
(43) Pub. Date: Nov. 28, 2024

(54) SEMICONDUCTOR DEVICE, SEMICONDUCTOR DEVICE ARRAY, AND WAFER

(71) Applicant: FURUKAWA ELECTRIC CO., LTD., Tokyo (JP)

(72) Inventors: Kenichiro YAO, Tokyo (JP); Masahiro YOSHIDA, Tokyo (JP)

(73) Assignee: FURUKAWA ELECTRIC CO., LTD., Tokyo (JP)

(21) Appl. No.: 18/794,039

(22) Filed: Aug. 5, 2024

Related U.S. Application Data
(63) Continuation of application No. PCT/JP2023/003110, filed on Jan. 31, 2023.

(30) Foreign Application Priority Data
Feb. 8, 2022 (JP) 2022-018040

(51) Int. Cl. H01S 5/042; H01S 5/40

(52) U.S. Cl. CPC H01S 5/04256; H01S 5/04254; H01S 5/4025

(57) ABSTRACT

A semiconductor device includes: a body including a substrate, a plurality of semiconductor layers layered on the substrate in a first direction, an end face in the first direction, and an edge configuring a periphery when the body is viewed in a direction opposite to the first direction; an insulating layer covering the end face; an electrode provided on the end face on a side opposite to the substrate; at least one wiring electrically connected to the electrode and extending between the electrode and the edge; a non-formation area in which the insulating layer is not formed, the non-formation area being provided on the end face along the edge; and an interposed portion included in the insulating layer, the interposed portion being interposed between the end face and the wiring in a position deviating from the non-formation area.

This application is a continuation of International Application No. PCT/JP2023/003110, filed on Jan. 31, 2023 which claims the benefit of priority of the prior Japanese Patent Application No. 2022-018040, filed on Feb. 8, 2022, the entire contents of which are incorporated herein by reference.

### BACKGROUND

The present disclosure relates to a semiconductor device, a semiconductor device array, and a wafer.

A technique of manufacturing a plurality of optical semiconductor devices by forming a plurality of optical semiconductor device segments by layering a semiconductor layer, a conductive layer, etc., on a wafer and by cutting the optical semiconductor device segments out of the wafer has been known (for example, Japanese Laid-open Patent Publication No. 2014-139996).

According to Japanese Laid-open Patent Publication No. 2014-139996, electrodes that are adjacent to each other on a wafer are electrically connected by wiring (conductive line). This inhibits occurrence of variation (individual variability) in the thickness of the electrodes due to a potential difference of each unit when the electrodes that are provided in each of the optical semiconductor devices in the process of manufacturing optical semiconductor devices are formed by electroplating. An insulating layer, such as a dielectric layer, is provided between an upper surface of the semiconductor layer and the wiring.

### SUMMARY

When the insulating layer is provided across the boundary between a plurality of optical semiconductor device segments on a wafer, there is a risk of occurrence of disadvantageous evets that the insulating layer is an obstacle and, for example, it is thus difficult to cut optical semiconductor device segments out of the wafer and the end face along which the optical semiconductor device including an active layer is cut tends to be rough. Disadvantageous events similar to this can happen in a semiconductor device that is not an optical semiconductor device.

There is a need for a semiconductor device, a semiconductor device array, and a wafer that are new and improved and that make it possible to execute cutting a plurality of semiconductor device segments out of a wafer more easily, in a more ensured manner, or more accurately.

According to one aspect of the present disclosure, there is provided a semiconductor device including: a body including a substrate, a plurality of semiconductor layers layered on the substrate in a first direction, an end face in the first direction, and an edge configuring a periphery when the body is viewed in a direction opposite to the first direction; an insulating layer covering the end face; an electrode provided on the end face on a side opposite to the substrate; at least one wiring electrically connected to the electrode and extending between the electrode and the edge; a non-formation area in which the insulating layer is not formed, the non-formation area being provided on the end face along the edge; and an interposed portion included in the insulating layer, the interposed portion being interposed between the end face and the wiring in a position deviating from the non-formation area.

According to another aspect of the present disclosure, there is provided a semiconductor device including: a body including a substrate, a plurality of semiconductor layers layered on the substrate in a first direction, an end face in the first direction, and an edge configuring a periphery when the body is viewed in a direction opposite to the first direction; an insulating layer covering the end face; an electrode provided on the end face; at least one wiring electrically connected to the electrode and extending between the electrode and the edge; and a non-formation area in which the insulating layer is not formed, the non-formation being provided on the end face along the edge, wherein the edge includes a first edge positioned on a front side and a back side in a second direction intersecting with the first direction, and a second edge positioned on a front side and a back side in a third direction intersecting with the first direction and the second direction, at least one the wiring includes a wiring extending between the electrode and the first edge, and there is no wiring extending between the electrode and the second edge.

According to still another aspect of the present disclosure, there is provided a semiconductor device array including: a body including a substrate, a plurality of semiconductor layers layered on the substrate in a first direction, an end face in the first direction, and a first edge positioned forward and backward in a second direction intersecting with the first direction when the body is viewed in a direction opposite to the first direction; an insulating layer covering the end face; a plurality of electrodes provided on the end face; at least one wiring electrically connected to the electrode and extending between the electrode and the edge; a plurality of semiconductor device segments arrayed in a third direction intersecting with the first direction and the second direction; a non-formation area in which the insulating layer is not formed, the non-formation area being provided on the end face along the first edge when the semiconductor device array is viewed in a direction opposite to the first direction; and an interposed portion included in the insulating layer, the interposed portion being interposed between the end face and the wiring in a position deviating from the non-formation area.

### BRIEF DESCRIPTION OF THE DRAWINGS

FIG. 1 is an exemplary and schematic plane view of a semiconductor device of a first embodiment;

FIG. 2 is a cross-sectional view taken along the line II-II in FIG. 1;

FIG. 3 is an exemplary and schematic plane view illustrating a wafer on which semiconductor device segments serving as a semiconductor device of the first embodiment are formed and part of the wafer;

FIG. 4 is a cross-sectional view taken along the line IV-IV in FIG. 1;

FIG. 5 is an exemplary and schematic plane view of a semiconductor device of a second embodiment;

FIG. 6 is an exemplary and schematic plane view of part of a wafer of a third embodiment;

FIG. 7 is an exemplary and schematic plane view of a semiconductor device of a fourth embodiment;

FIG. 8 is an exemplary and schematic plane view of a semiconductor device of a fifth embodiment;

FIG. 9 is an exemplary and schematic plane view of a semiconductor device of a sixth embodiment;

FIG. 10 is an exemplary and schematic plane view of part of a wafer of a seventh embodiment;

FIG. 11 is an exemplary and schematic plane view of an XI portion in FIG. 10; and

FIG. 12 is an exemplary and schematic plane view of a semiconductor device array that is cut out of the wafer of the seventh embodiment.

### DETAILED DESCRIPTION

An exemplary embodiment of the present disclosure will be disclosed below. A configuration of the embodiment and the function and the result (effect) brought by the configuration that are illustrated below are an example. The present disclosure can be realized by a configuration other than the configuration disclosed in the following embodiment. According to the disclosure, it is possible to obtain at least one of various effects (including derivative effects) that are obtained with the configuration.

A plurality of embodiments illustrated below include similar configurations. Thus, according to the configurations of the respective embodiments, similar functions and effects based on the similar configurations are obtained. Similar reference numerals are assigned to the similar configurations and redundant descriptions will be omitted in some cases below.

In the specification, ordinal numbers are assigned for convenience in order to distinguish directions parts, portions, etc., and do not represent priorities and an order.

In each of the drawings, an X-direction is denoted with an arrow X, a Y-direction is denoted with an arrow Y, and an Z-direction is denoted with an arrow Z. The X-direction, the Y-direction, and the Z-direction intersect with one another and are orthogonal with one another. The X-direction is referred to as a longitudinal direction or an extension direction, the Y-direction is referred to as a transversal direction or a width direction, and the Z-direction is referred to as a layering direction or a height direction.

Each of the drawings is a schematic view for the purpose of explanation and each of the drawings and an actual one do not necessarily match in scale and ratio.

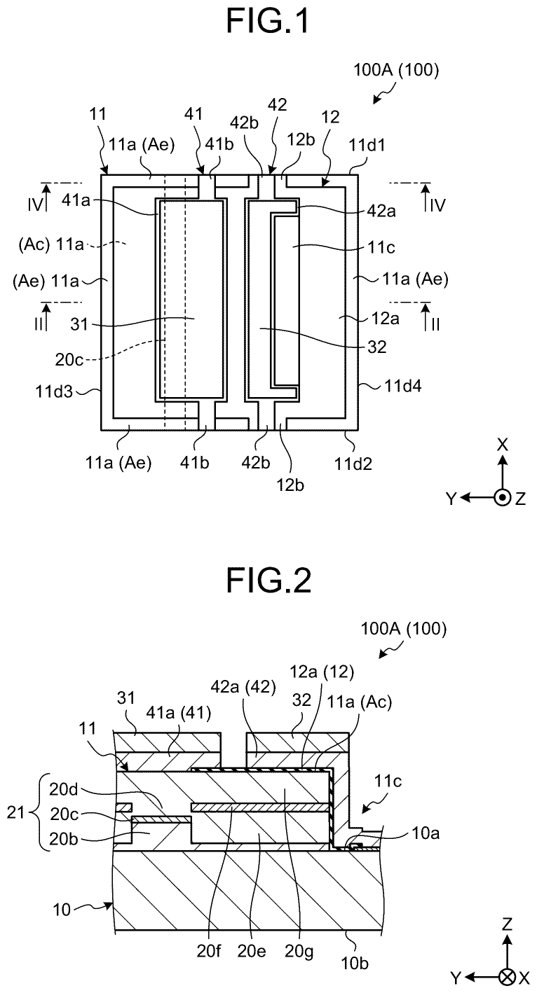

FIG. 1 is a plane view of a semiconductor device 100A (100) of the first embodiment and FIG. 2 is a cross-sectional view taken along the line II-II in FIG. 1. The semiconductor device 100A, for example, is configured as a known semiconductor optical amplifier.

As illustrated in FIGS. 1 and 2, the semiconductor device 100A includes a body 11 containing a substrate 10 and a plurality of semiconductor layers, an insulating layer 12 that is formed on the body 11, electrodes 31 and 32, and conductive layers 41 and 42 that are electrically connected to the electrodes 31 and 32.

The body 11 contains a second layer 20c that extends in the X-direction and that serves as an active layer. The second layer 20c extends approximately in the X-direction in a given width in the Y-direction and in a given height in the Z-direction in an approximately certain position in the Z-direction.

As illustrated in FIG. 2, the substrate 10 has an thickness that is approximately constant in the Z-direction, intersects with the Z-direction, and extends. As illustrated in FIG. 2, the substrate 10 has a face 10a and a face 10b. The face 10a is directed in the Z-direction and intersects with the Z-direction. The face 10b is positioned on a side opposite to the face 10a, is directed in a direction opposite to the Z-direction, and intersects with the Z-direction. The substrate 10 is made of, for example, n-InP.

In the body 11, for example, the semiconductor layers, such as first to third layers 20b to 20d, current blocking layers 20e and 20f, and a cladding layer 20g, are layered on the face 10a of the substrate 10 in the Z-direction. The Z-direction is an example of a first direction.

The body 11 further has a mesa 21 including a first to third layers 20b to 20d. As described above, the second layer 20c contained in the mesa 21 is an active layer and functions as an optical waveguide. The body 11 includes a buried waveguide structure (BH waveguide structure).

The first layer 20b is made of, for example, n-InP and, in the mesa 21, functions as a cladding layer.

The second layer 20c has, for example, a layered structure containing n-InGaAsP and is what is referred to as a quaternary layer. The second layer 20c functions as an active layer and thus, for example, has a composition that functions appropriately with respect to light of a wavelength of a 1.55 [μm] band.

The third layer 20d is made of, for example, p-InP and functions as a cladding layer in the mesa 21.

In the body 11, the mesa 21 is surrounded by the current blocking layers 20e and 20f and the cladding layer 20g that is adjacent in the Z-direction. The current block blocking layer 20e is made of, for example, p-InP and the current blocking layer 20f is made of, for example, n-InP. The cladding layer 20g is made of, for example, p-InP. The conductive layers 41 and 42 are provided on the cladding layer 20g, that is, on a side opposite to the substrate 10 with respect to the cladding layer 20g. The electrode 31 is provided on the conductive layer 41, that is, on a side opposite to the substrate 10 with respect to the conductive layer 41 and the electrode 32 is provided on the conductive layer 42, that is, on a side opposite to the substrate 10 with respect to the conductive layer 42. The polarities of the electrodes 31 and 32 are different from each other.

The electrode 31 separates from the active layer in the Z-direction and configures a P-side electrode. It can be described that the conductive layer 41 also configures part of the P-side electrode.

End faces (side surfaces) of the body 11 in the Y-direction and a direction opposite to the Y-direction and an end face 11a (upper surface) of the body 11 in the Z-direction excluding an opening penetrating the conductive layer 41 are covered with the insulating layer 12 on the body 11. In other words, the conductive layer 41 makes contact with the end face 11a and the electrode 31 is electrically connected to the end face 11a via the conductive layer 41. Note that the insulating layer 12 is made of, for example, SiN.

The insulating layer 12 is interposed between the end face 11a and the conductive layer 42 and the electrode 32.

In other words, the conductive layer 42 and the electrode 32 are insulated from the end face 11a. The conductive layer 42 separates from the conductive layer 41 in the Y-direction and extends to a side surface and a bottom surface of a concave portion 11c that is formed on the body 11. An opening is formed on the insulating layer 12 at the bottom surface of the concave portion 11c and the conductive layer 42 is electrically connected to the substrate 10 in the opening.

Applying a voltage between the electrodes 31 and 32 enables a current to flow through the semiconductor layers. When the semiconductor device 100 is configured as an optical semiconductor device, such as a semiconductor optical amplifier, it is possible to activate the second layer 20c with the current.

As illustrated in FIG. 1, the body 11 has a rectangular shape in a plane view of the body 11 viewed in the direction opposite to the Z-direction. The body 11 includes edges 11d1, 11d2, 11d3, and 11d4 that form the periphery in the plane view. The edge 11d1 extends along the Y-direction at an end in the X-direction. The edge 11d2 extends along the Y-direction at an end in a direction opposite to the X-direction. The edge 11d3 extends along the X-direction at an end in the Y-direction. The edge 11d4 extends along the X-direction at an end in the direction opposite to the Y-direction. The edges 11d1 and 11d2 are an example of a first edge and the edges 11d3 and 11d4 are an example of a second edge. The X-direction is an example of a second direction and the Y-direction is an example of a third direction.

The end face 11a is covered with the insulating layer 12. The insulating layer 12 has a covering portion 12a that covers over the end face 11a excluding the above-described opening penetrating the conductive layers 41 and 42. The periphery of the covering portion 12a separates from the edges 11d1, 11d2, 11d3 and 11d4. In other words, the end face 11a has a covered area Ac that is covered with the covering portion 12a and a non-formation area Ae in which the covering portion 12a (the insulating layer 12) is not formed along the edges 11d1, 11d2, 11d3 and 11d4. The non-formation area Ae extends in a width that is approximately constant along the edges 11d1, 11d2, 11d3 and 11d4; however, the width need not be constant. The non-formation area Ae can be also referred to as an exposure area.

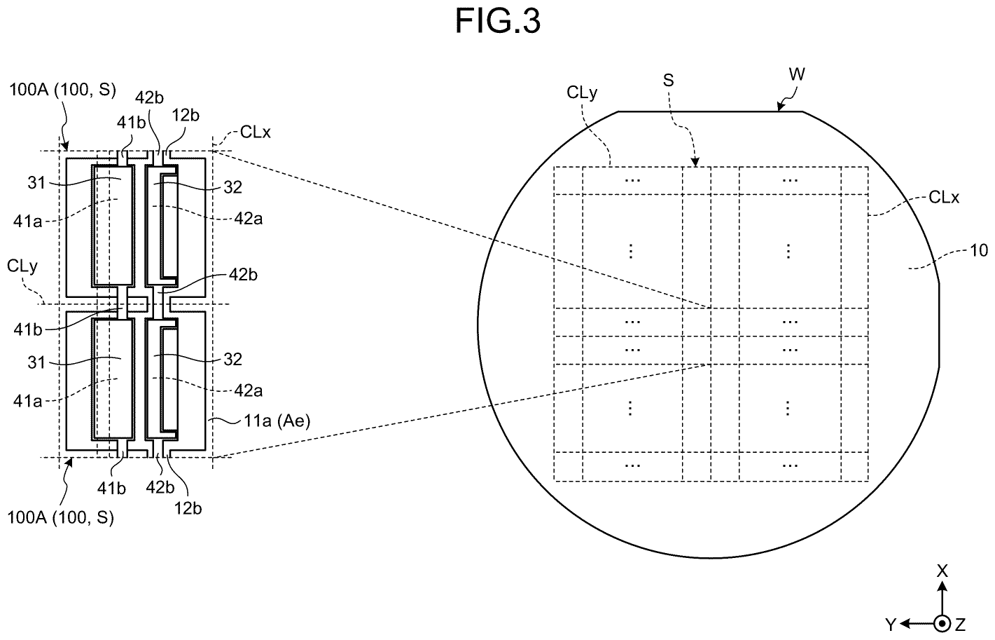

FIG. 3 is a plane view illustrating a wafer W and part on the wafer W in an enlarged manner. As illustrated in FIG. 3, a plurality of semiconductor device segments S arranged in a matrix are collectively formed on the substrate 10 of the wafer W by a semiconductor process and the semiconductor element portions S are cut out along a cut line CLx extending in the X-direction and a cut line CLy extending in the Y-direction, so that the semiconductor device 100A (100) is obtained. In other words, the semiconductor device segments S have approximately the same configuration as that of the semiconductor device 100. The cut line CLx serves as the edges 11d1 and 11d2 in the semiconductor device 100 and the cut line CLy serves as the edges 11d3 and 11d4 in the semiconductor device 100. Note that the cut lines CLx and CLy can be also referred to as cut due lines or virtual boarder lines.

When the cut lines CLx and CLy are covered with the insulating layer 12, there is a risk that, because of the presence of the insulating layer 12, disadvantageous events that it is difficult to cut the wafer W along the cut line sCLx and CLy and the edges 11d1, 11d2, 11d3 and 11d4 serving as the cut end faces of the semiconductor device 100A that is cut out are rough and irregularities occur may be caused. For this reason, in the first embodiment, the non-formation area Ae where the insulating layer 12 is not formed is provided along the cut lines CLx and CLy on the end face 11a of the wafer W in a form of bands with the cut lines CLx and CLy being at the center. This makes it possible to avoid occurrence of disadvantageous events caused by the insulating layer 12 in cutting along the cut lines CLx and CLy.

Similarly to other components of the semiconductor device 100A (100), the electrodes 31 and 32 are formed in a state where the semiconductor device segments S are unified on the wafer W. The electrodes 31 and 32 are formed by plating such that the electrodes 31 and 32 have given forms in given positions on the conductive layers 41 and 42 that are provided in each of the semiconductor device segments S. When the electrodes 31 and 32 are formed by electroplating, a large difference in potential between the conductive layers 41 or the conductive layers 42 on the wafer W has a risk of causing variation (individual variability) in the thickness of the electrodes 31 and 32 in the Z-direction, or the like. Such variation in the shape of the electrodes 31 and 32 has a risk of being a cause of variation (individual variability) in performance between the semiconductor devices 100.

In the first embodiment, as illustrated in FIG. 3, wiring portions 41b and 42b are provided in the conductive layers 41 and 42 of each of the semiconductor device segments S (the semiconductor device 100). The wiring portion 41b electrically connects a plurality of covering portions 41a that are adjacent to each other in the X-direction on the wafer W. The wiring portion 42b electrically connects a plurality of covering portions 42a that are adjacent to each other in the X-direction on the wafer W. Accordingly, on the wafer W, the covering portions 41a are electrically connected via the wiring portions 41b and the covering portions 42a are electrically connected via the wiring portions 42b in a row of the semiconductor device segments S that are arrayed in the X-direction. Thus, according to the first embodiment, it is possible to further reduce the potential difference between the conductive layers 41 and between the conductive layers 42 between the semiconductor device segments S in electroplating that forms the electrodes 31 and 32 and thus it is possible to inhibit occurrence of variation in the specification of the electrodes 31 and 32 between a plurality of the semiconductor devices 100 and eventually inhibit occurrence of variation in performance between the semiconductor devices 100. Note that, in the semiconductor device 100, the wiring portion 41b extends between the electrode 31 and the edge 11d1 or the edge 11d2 and the wiring portion 42b extends between the electrode 32 and the edge 11d1 or the edge 11d2. The wiring portions 41b and 42b are an example of wiring.

As described above, on the wafer W, while the insulating layer 12 is not provided in the non-formation area A2 along the cut lines CLx and CLy, the wiring portions 41b and 42b are over the cut line CLy. If both the wiring portions 41b and 42b that are electrically connected respectively to the electrodes 31 and 32 whose polarities are different from each other make contact with the non-formation area Ae of the end face 11a, there is a risk that current short-circuiting will occur between the wiring portions 41b and 42b.

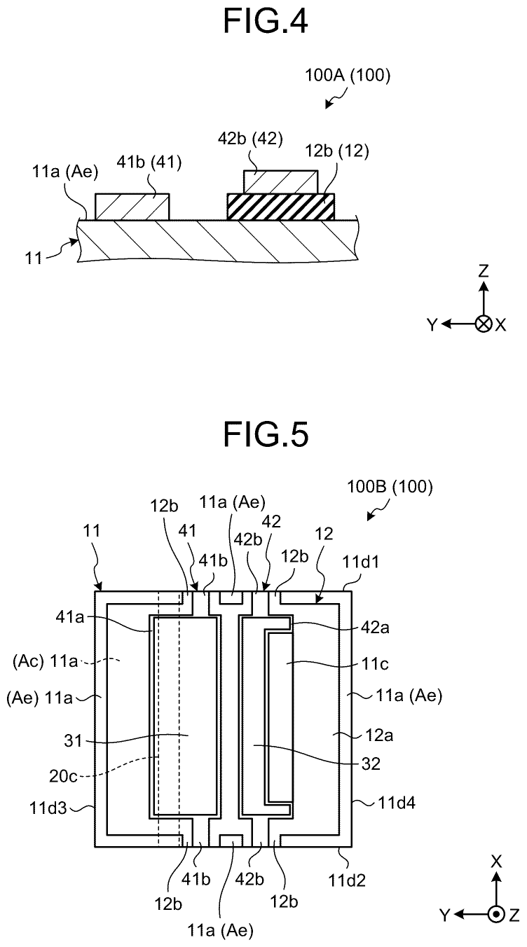

Thus, the semiconductor device segment S (the semiconductor device 100) of the first embodiment is provided with a configuration for preventing current short-circuiting between the wiring portions 41b and 42b via the non-formation area Ae where the insulating layer 12 is not formed. FIG. 4 is a cross-sectional view taken along the line IV-IV in FIG. 1. As illustrated in FIG. 4, in the first embodiment, an interposed portion 12b that is interposed between the wiring portion 42b and the end face 11a in accordance with one of the wiring portions 41b and 42b, the wiring portion 42b as an example in the first embodiment, in the non-formation area Ae. As illustrated in FIG. 1, the interposed portion 12b extends to a front side in the X-direction and a back side in the X-direction from the covering portion 12a of the insulating layer 12 in the position in which the wiring portion 42b is provided and divides the non-formation area Ae. In other words, the interposed portion 12b is interposed between the wiring portion 42b and the end face 11a in the position deviating from the non-formation area Ae. Note that the wiring portion 41b is provided on the non-formation area Ae and is an example of a first wiring. The wiring portion 42 is provided on the interposed portion 12b and is an example of a second wiring. The electrode 31 is an example of a first electrode and the electrode 32 is an example of a second electrode.

As described above, in the first embodiment, as for the position in which the wiring portion 42b is provided, the interposed portion 12b serving as the insulating layer 12 is provided. A section in which the interposed portion 12b is provided on the cut lines CLx and CLy however is relatively short and the insulating layer 12 is not provided in other sections on the cut lines CLx and CLy and therefore it is possible to prevent such a disadvantageous event caused by the insulating layer 12 as described above in cutting along the cut lines CLx and CLy.

As described above, according to the first embodiment, providing the non-formation area Ae in which the insulating layer 12 is not formed along the cut lines CLx and CLy makes it possible to, while avoiding occurrence of a disadvantageous event caused by the insulating layer 12 in cutting the wafer W, inhibit variation between the electrodes 31 and 32 that are formed by electroplating on the wager W by providing the wiring portions 41b and 42b. Furthermore, because the interposed portion 12b is partially provided as the insulating layer 12 in accordance with the wiring portion 42b, an effect that it is possible to, while avoiding occurrence of a disadvantageous event caused by the insulating layer 12 in cutting the wafer W, prevent current short-circuiting between the wiring portions 41b and 42b that are provided to inhibit variation between the electrodes 31 and 32 in the semiconductor device 100 is obtained.

Furthermore, as described above, in the first embodiment, the wiring portion 42b (the conductive layer 42) is electrically connected to the substrate 10. In such a configuration, if the wiring portion 42b makes contact with the non-formation area Ae of the end face 11a, unwilling current short-circuiting around the semiconductor layers including the second layer 20c occurs between the end face 11a and the substrate 10 via the conductor layer 42. In this respect, according to the first embodiment, providing the interposed portion 12b between the wiring portion 42b that is electrically connected to the substrate 10 and the non-formation area Ae makes it possible to prevent unwilling current short-circuiting between the end face 11a and the substrate 10.

Cutting the semiconductor device segments S that are adjacent to each other in the Y-direction in an unified state out of the wafer W makes it possible to obtain a semiconductor device array (not illustrated in the drawing). Such a configuration, for example, is suitable to be applied to an optical device including a plurality of semiconductor optical amplifiers, such as an optical matrix switch.

FIG. 5 is a plane view of a semiconductor device 100B (100) of a second embodiment. As illustrated in FIG. 5, in the second embodiment, the interposed portion 12b is provided not only between the wiring portion 42b and the end face 11a but also between the wiring portion 41b and the end face 11a. Also according to the second embodiment, the same effect as that of the first embodiment is obtained. The provision may be made in a position deviating from the interposed portion 12b as long as it is possible to avoid occurrence of a disadvantageous event caused by the insulating layer 12 in cutting the wafer Q. In other words, the length of the non-formation area Ae along the edges 11d1 to 11d4 in the non-formation area Ae may be shorter.

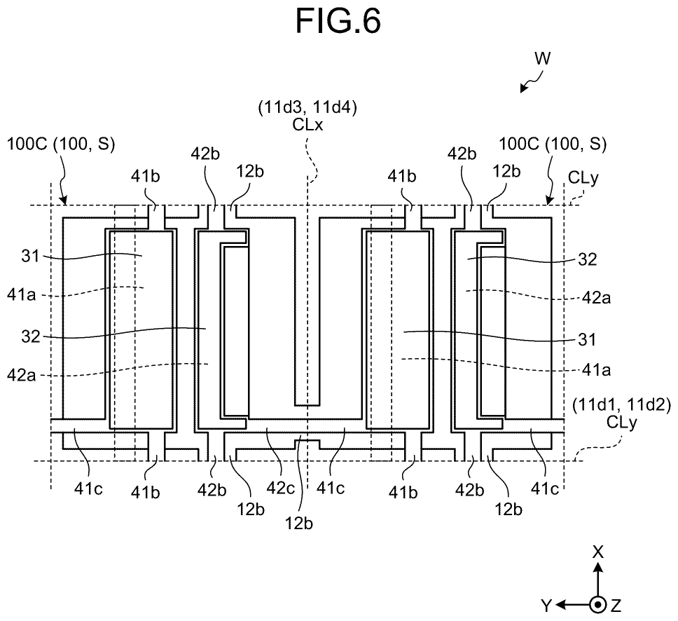

FIG. 6 is a plane view of the wafer W of a third embodiment. As illustrated in FIG. 6, wiring portions 41c and 42c are provided on the wafer W of the third embodiment in addition to the same wiring portions 41b and 42b as those of the above-described embodiment. The wiring portions 41c and 42c electrically connect the electrodes 31 and 32 that are adjacent to each other in the Y-direction in two semiconductor device segments S that are adjacent to each other in the Y-direction.

Specifically, the wiring portion 41c extends from the covering portion 41a of the conductive layer 41 to the cut line CLx in the Y-direction and the wiring portion 42c extends from the covering portion 42a of the conductive layer 42 to the cut line CLx in a direction opposite to the Y-direction. In the wafer W, an end of the wiring portion 41c and an end of the wiring portion 42c on the cut line CLx face each other and are electrically connected to each other. Because of such a configuration, in a semiconductor device 100C that is cut out of the wafer W, the end of the wiring portion 41c at the edge 11d3 and the end of the wiring portion 42c at the edge 11d4 are aligned in the Y-direction.

According to the third embodiment, in electroplating that forms the electrodes 31 and 32, the wiring portions 41b, 42b, 41c and 42c make it possible to electrically connect more covering portions 41a and 42a and further reduce the potential difference between the covering portions 41a and 42a. Thus, according to the third embodiment, it is possible to further inhibit occurrence of variation in the specification of the electrodes 31 and 32 between a plurality of the semiconductor devices 100 and eventually inhibit occurrence of variation in performance between the semiconductor devices 100. Note that, in the third embodiment, both the wiring portions 41c and 42c are provided on the interposed portions 12b and are an example of the second wiring.

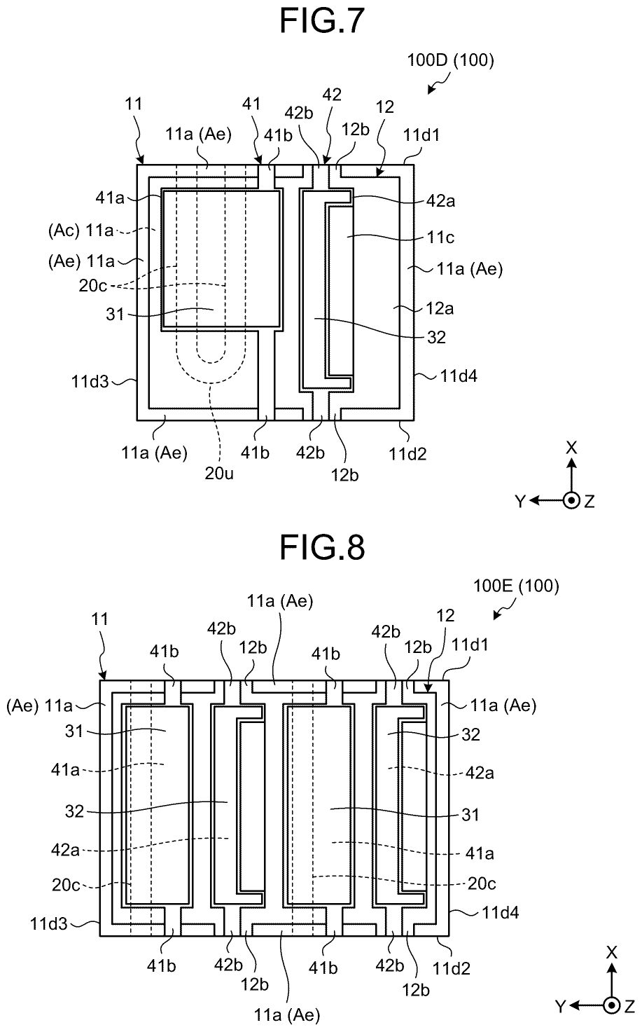

FIG. 7 is a plane view of a semiconductor device 100D (100) of a fourth embodiment. As illustrated in FIG. 7, the semiconductor device 100D of the fourth embodiment has a waveguide that is U-shaped and that includes two second layers 20c arranged in approximately in the same position in the Z-direction and a passive portion 20u. Both the two second layers 20c extend in the X-direction and are arranged approximately in parallel with an interval in the Y-direction. The passive portion 20u curves in a shape convex in the direction opposite to the X-direction and connects ends of the two second layers 20c in the direction opposite to the X-direction.

The semiconductor device 100D of the fourth embodiment includes the non-formation area Ae, the wiring portions 41b and 42b, and the interposed portion 12b that are the same as those of the first embodiment. Also according to the fourth embodiment, the same effect as that of the first embodiment is obtained.

FIG. 8 is a plane view of a semiconductor device 100E (100) of a fifth embodiment. As illustrated in FIG. 8, the semiconductor device 100E of the fifth embodiment includes two second layers 20c and has the same configuration as that in FIG. 1 and FIG. 2 corresponding to each of the second layers 20c. In other words, the semiconductor device 100E has two sets of the same configuration as that of the above-described first embodiment. It is possible to cause each of the two second layers 20c to operate independently.

The semiconductor device 100E of the fifth embodiment includes the non-formation area Ae, the wiring portions 41b and 42b, and the interposed portion 12b that are the same as those of the first embodiment. Also according to the fifth embodiment, the same effect as that of the first embodiment is obtained. As for the semiconductor device 100 including three sets of the second layer 20c and the configuration corresponding to the second layer 20c, when the semiconductor device 100 includes the non-formation area Ae, the wiring portions 41b and 42b, and the interposed portion 12b as in the first embodiment, the same effect as that of the first embodiment is obtained.

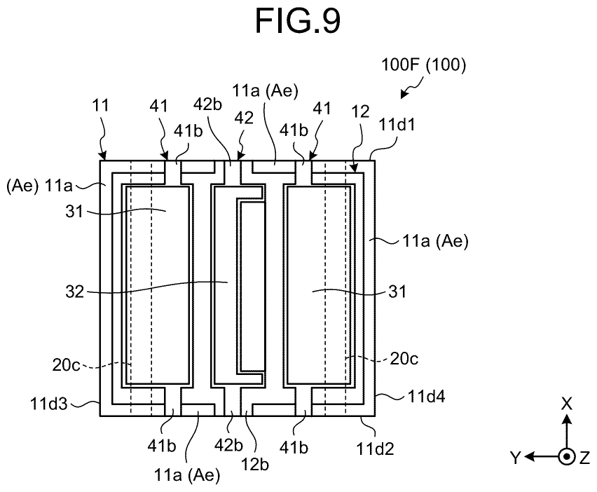

FIG. 9 is a plane view of a semiconductor device 100F (100) of a sixth embodiment. As illustrated in FIG. 9, the semiconductor device 100F of the sixth embodiment also includes two second layers 20c as in the fifth embodiment.

Note that, in the sixth embodiment, as for the operation of the two second layers 20c, the electrode 32 is shared. The semiconductor device 100F thus includes the two electrodes 31 and one electrode 32.

The semiconductor device 100E of the sixth embodiment includes the non-formation area Ae, the wiring portions 41b and 42b, and the interposed portion 12b that are the same as those of the first embodiment. Also according to the sixth embodiment, the same effect as that of the first embodiment is obtained.

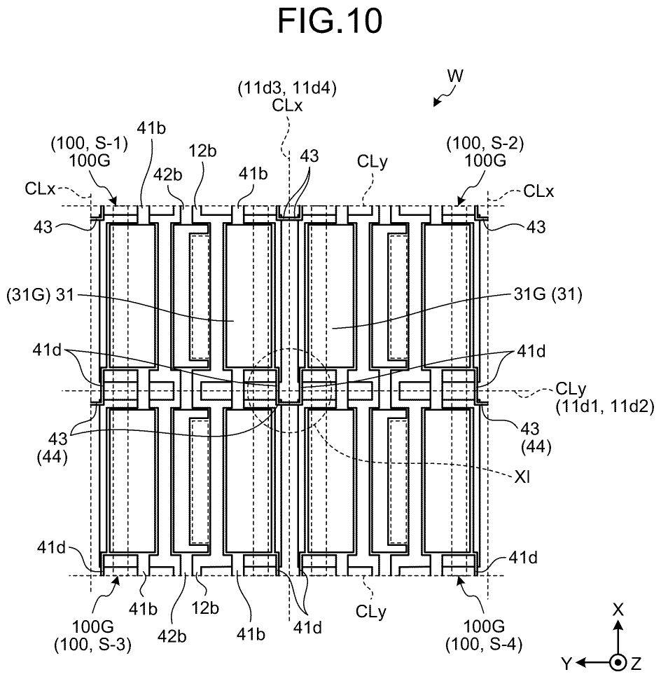

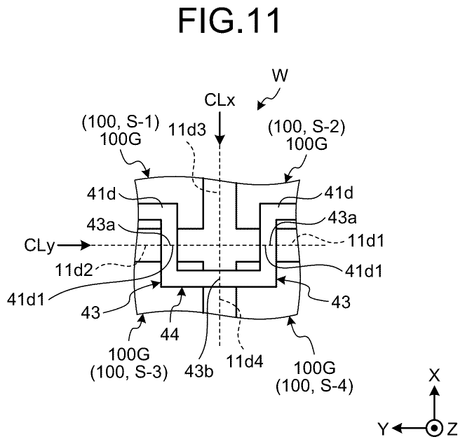

FIG. 10 is a plane view of the wafer W of a seventh embodiment. FIG. 11 is an enlarged view of an XI portion in FIG. 10.

As illustrated in FIG. 10, a plurality of semiconductor device segments S-1 to S-4 (a semiconductor device 100G) that are formed on the wafer W have approximately the same configuration as that of the semiconductor device 100F of the sixth embodiment. Note that wiring portions 41d and 43 are provided on the wafer W of the seventh embodiment in addition to the same wiring portions 41b and 42b as those of the above-described embodiment. The wiring portions 41d and 43 electrically connect electrodes 31G (31) that are adjacent to each other in the Y-direction in two semiconductor device segments S-1 and S-2 that are adjacent to each other in the Y-direction. The wiring portions 41d and 43 run through the four semiconductor device segments S-1 to S-4.

As illustrated in FIGS. 10 and 11, each of the wiring portions 41d that are provided in the semiconductor device segments S-1 and S-2 extends from the electrode 31 in the direction opposite to the X-direction to the cut line CLy (the edge 11d2). On the other hand, each of the wiring portions 43 that are provided in the semiconductor device segments S-3 and S-4 has a L-like shape and extends between the cut line CLy (the edge 11d1) and the cut line CLx (the edge 11d3 or the edge 11d4). In the wafer W, an end 41d1 of the wiring portion 41d and an end 43a of the wiring portion 43 on the cut line CLy face each other and are electrically connected to each other. Ends 43b of the two wiring portions 43 on the cut line CLx face each other and are electrically connected to each other. Thus, in the semiconductor device 100G that is cut out of the wafer W, the end 43a of the wiring portion 43 at the edge 11d1 and the end 41d1 of the wiring portion 41d at the edge 11d2 are aligned in the X-direction and the end 43b of the wiring portion 32 at the edge 11d3 and the end 43b of the wiring portion 43 at the edge 11d4 are aligned in the Y-direction.

Also according to the seventh embodiment, in electroplating that forms the electrodes 31 and 32, as according to the third embodiment, the wiring portions 41b, 42b, 41d and 43 make it possible to electrically connect more covering portions 41a and 42a and further reduce the potential difference between the covering portions 41a and 42a. Thus, according to the seventh embodiment, it is possible to further inhibit occurrence of variation in the specification of the electrodes 31 and 32 between a plurality of the semiconductor devices 100 and eventually inhibit occurrence of variation in performance between the semiconductor devices 100.

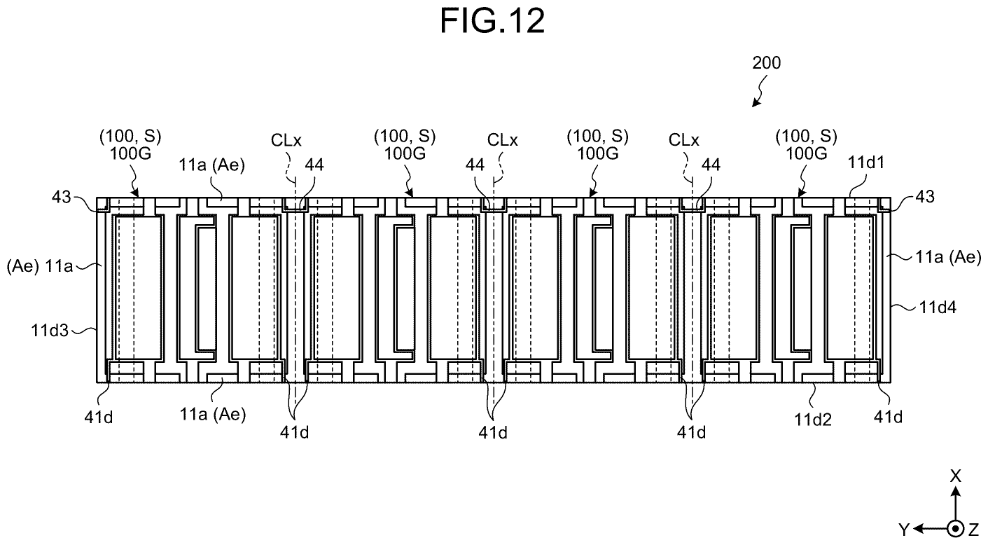

FIG. 12 is a plane view of a semiconductor device array 200 including a plurality of the semiconductor device segments S of the seventh embodiment that are arrayed in the Y-direction in a unified manner. As illustrated in FIG. 12, the semiconductor device array 200 includes the wiring portions 41b, 42b, 41d and 43 and a wiring portion 44 that has the wiring portions 43 adjacent to each other in the Y-direction in a unified manner. The wiring portions 41b, 42b and 41d extend between the electrode 31 or the electrode 32 and the edge 11d1 or the edge 11d2. On the other hand, the wiring portions 43 and 44 are not connected to any of the electrodes 31 and 32, have a U-like shape or an L-like shape, and extend between the edge 11d1 and the edges 11d1, 11d3 or 11d4. If a semiconductor device array including a plurality of the semiconductor device segments S of the third embodiment (refer to FIG. 6) that are aligned in the Y-direction in a unified manner is configured, it is not possible to use the semiconductor device array because the electrodes 31 and 32 that are adjacent to each other in the Y-direction are electrically connected via the wiring portions 41c and 42c and are short-circuited. This is because the wiring portions 41c and 42c that electrically connect the electrodes 31 and 32 on the wafer W go through only the cut line CLx along which no cutting is performed when the semiconductor device array is configured. In the respect, on the wafer W of the seventh embodiment, as illustrated in FIG. 11, because the wiring portions 41d, 43 and 44 extending between the electrodes 31 and 32 that are adjacent in the Y-direction go through the cut line CLy along which cutting is performed when the semiconductor device array 200 is configured and thus are separated on the cut line CLy, it is possible to obtain the semiconductor device array 200 in which the electrodes 31 and 32 are not short-circuited because of the wiring portions 41d, 43 and 44.

To enable such a configuration of the semiconductor device array 200, the semiconductor device segment S (the semiconductor device 100G) of the seventh embodiment includes the wiring portions 41b, 42b and 41d extending between the electrodes 31 and 32 and the edges 11d1 and 11d2 and does not include wiring portions extending between the electrodes 31 and 32 and the edges 11d3 and 11d4. The electrodes 31 and 32 are electrically insulated in the semiconductor device 100G and the semiconductor device 100G includes the wiring portion 43 extending between the edge 11d1 and the edge 11d3 or the edge 11d4. The wiring portion 43 is an example of a third wiring.

The semiconductor device array 200 according to the seventh embodiment includes the U-shaped wiring portion 44 (refer to FIG. 12) that extends between two ends 43a facing the edge 11d1 and being separated in the Y-direction (refer to FIG. 11). The wiring portion 44 is approximately aligned in the X-direction with the two wiring portions 41d facing the edge 11d2. The wiring portion 44 is an example of a fourth wiring.

The embodiments of the disclosure are exemplified above and the above-described embodiments are an example and are not intended to limit the scope of the disclosure. It is possible to carry out the above-described embodiments in other various modes and various omissions, replacements, combinations and changes without departing from the scope of the disclosure. It is possible to change and practice the specification, such as each configuration and shape, (structure, type, direction, model, size, length, width, thickness, height, number, arrangement, position, material, etc.,) as appropriate.

For example, an optical semiconductor device is applicable to, for example, a laser light emitting device, such as a DFB-type semiconductor laser, a semiconductor device that is not an optical semiconductor device, etc.

The present disclosure is usable for a semiconductor device, a semiconductor device array, and a wafer.

According to the disclosure, it is possible to obtain a semiconductor device, a semiconductor device array, and a wafer that are new and improved.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor device comprising:
a body including
a substrate,
a plurality of semiconductor layers layered on the substrate in a first direction,
an end face in the first direction, and
an edge configuring a periphery when the body is viewed in a direction opposite to the first direction;
an insulating layer covering the end face;
an electrode provided on the end face on a side opposite to the substrate;
at least one wiring electrically connected to the electrode and extending between the electrode and the edge;
a non-formation area in which the insulating layer is not formed, the non-formation area being provided on the end face along the edge; and
an interposed portion included in the insulating layer, the interposed portion being interposed between the end face and the wiring in a position deviating from the non-formation area.

2. The semiconductor device according to claim 1, wherein
the semiconductor device is an optical semiconductor device,
the semiconductor layer includes an active layer, and
the electrode is configured to supply a current to the active layer.

3. The semiconductor device according to claim 1, wherein
the wiring includes a plurality of wirings, and
the plurality of wirings include a first wiring provided on the non-formation area and a second wiring provided on the interposed portion.

4. The semiconductor device according to claim 3, wherein
the electrode includes a first electrode and a second electrode that have different polarities from each other,
the first wiring is electrically connected to the first electrode, and
the second wiring is electrically connected to the second electrode.

5. The semiconductor device according to claim 4, wherein the second electrode is electrically connected to the substrate.

6. The semiconductor device according to claim 1, wherein
the edge includes:
a first edge positioned on a front side and a back side in a second direction intersecting with the first direction; and
a second edge positioned on a front side and a back side in a third direction intersecting with the first direction and the second direction,
the at least one wiring includes a wiring extending between the electrode and the first edge, and
there is no wiring extending between the electrode and the second edge.

7. The semiconductor device according to claim 6, further comprising a third wiring extending between the first edge and the second edge, the third wiring being not electrically connected to the electrode.

8. A semiconductor device comprising:
a body including
a substrate,
a plurality of semiconductor layers layered on the substrate in a first direction,
an end face in the first direction, and
an edge configuring a periphery when the body is viewed in a direction opposite to the first direction;
an insulating layer covering the end face;
an electrode provided on the end face;
at least one wiring electrically connected to the electrode and extending between the electrode and the edge; and
a non-formation area in which the insulating layer is not formed, the non-formation being provided on the end face along the edge, wherein
the edge includes
a first edge positioned on a front side and a back side in a second direction intersecting with the first direction, and
a second edge positioned on a front side and a back side in a third direction intersecting with the first direction and the second direction,
at least one the wiring includes a wiring extending between the electrode and the first edge, and
there is no wiring extending between the electrode and the second edge.

9. A semiconductor device array comprising:
a body including
a substrate,
a plurality of semiconductor layers layered on the substrate in a first direction,
an end face in the first direction, and
a first edge positioned forward and backward in a second direction intersecting with the first direction when the body is viewed in a direction opposite to the first direction;
an insulating layer covering the end face;
a plurality of electrodes provided on the end face;
at least one wiring electrically connected to the electrode and extending between the electrode and the edge;
a plurality of semiconductor device segments arrayed in a third direction intersecting with the first direction and the second direction;
a non-formation area in which the insulating layer is not formed, the non-formation area being provided on the end face along the first edge when the semiconductor device array is viewed in a direction opposite to the first direction; and
an interposed portion included in the insulating layer, the interposed portion being interposed between the end face and the wiring in a position deviating from the non-formation area.

10. The semiconductor device array according to claim 9, wherein the semiconductor device segments have substantially a same configuration.

11. The semiconductor device array according to claim 9 further comprising:
two first wirings configured to serve as the wiring, extending between each of the electrodes adjacent to each other in the second direction and the first edge on any one of a front side and a back side in the second direction, and being aligned with an interval in the third direction, and
a fourth wiring including two ends positioned at a first edge on another side of the front side and the back side in the second direction and aligned with an interval in the third direction, the fourth wiring extending between the two ends via a position separating from the first edge on the other side, and being aligned with the two first wirings in the second direction.

12. The semiconductor device array according to claim 9, wherein each of the semiconductor device segments is configured as an optical semiconductor device segment including an active layer serving as the semiconductor layer and the electrode configured to supply a current to the active layer.

13. A wafer comprising
a plurality of semiconductor device segments arrayed in a matrix in the second direction intersecting with the first direction and the third direction intersecting with the first direction and the second direction,
wherein the wafer is configured such that the semiconductor device segment that is cut out of the wafer serves as the semiconductor device according to claim 1, and
the electrode includes a plurality of electrodes electrically connected via the wiring.

14. A wafer comprising
a plurality of semiconductor device segments arrayed in a matrix in the second direction intersecting with the first direction and the third direction intersecting with the first direction and the second direction,
wherein the wafer is configured such that the semiconductor device segment that is cut out of the wafer serves as the semiconductor device according to claim 8, and
the electrode includes a plurality of electrodes electrically connected via the wiring.

15. A wafer comprising
a plurality of semiconductor device segments arrayed in a matrix in the second direction intersecting with the first direction and the third direction intersecting with the first direction and the second direction,
wherein the wafer is configured such that the semiconductor device segment that is cut out of the wafer serves as the semiconductor device array according to claim 9, and
the electrode includes a plurality of electrodes electrically connected via the wiring.

16. The wafer according to claim 13, wherein each of the semiconductor device segments is configured as an optical semiconductor device segment including an active layer serving as the semiconductor layer and the electrode configured to supply a current to the active layer.
